(19) United States
(12) Patent Application Publication
(10) Pub. No.: US 2025/0253200 A1
(43) Pub. Date: Aug. 7, 2025

(54) SEMICONDUCTOR DEVICE AND SEMICONDUCTOR MODULE

(71) Applicant: Mitsubishi Electric Corporation, Tokyo (JP)

(72) Inventors: Yosuke NAKATA, Tokyo (JP); Kohei EBIHARA, Tokyo (JP)

(73) Assignee: Mitsubishi Electric Corporation, Tokyo (JP)

(21) Appl. No.: 18/959,487

(22) Filed: Nov. 25, 2024

(30) Foreign Application Priority Data
Feb. 1, 2024 (JP) 2024-013915

(51) Int. Cl. H01L 23/31

(52) U.S. Cl. CPC H01L 23/3192; H01L 23/3171

(57) ABSTRACT

A semiconductor device includes a semiconductor substrate in which a cell portion and a termination portion are defined, an electrode provided on an upper surface of the cell portion, a withstand voltage holding structure that is provided in the termination portion and holds a withstand voltage, an insulating protective film covering an upper surface of the withstand voltage holding structure, a waterproof film covering at least the insulating protective film, and an organic protective film covering a part of the waterproof film. The outer peripheral end portion of the electrode sits on the inner peripheral end portion of the insulating protective film. The inner peripheral end portion of the organic protective film sits on the outer peripheral end portion of the electrode. An outer peripheral end of the organic protective film is located on the inner peripheral side relative to the outer peripheral end of the insulating protective film.

### BACKGROUND OF THE INVENTION

### Field of the Invention

The present disclosure relates to a semiconductor device and a semiconductor module.

### Description of the Background Art

For example, Japanese Patent Application Laid-Open No. 2023-27528 discloses a silicon carbide semiconductor device having a structure in which a polyimide protective film (corresponding to an organic protective film) is provided on a termination region (corresponding to a termination portion) of a semiconductor substrate with a protective oxide film (corresponding to an insulating protective film) and a silicon nitride film (corresponding to a waterproof film) interposed therebetween, and an outer peripheral end portion of the silicon nitride film is exposed from the polyimide protective film.

When a temperature humidity bias (THB) test is performed on the semiconductor device described in Japanese Patent Application Laid-Open No. 2023-27528, a crack may occur in the silicon nitride film due to a step formed in an outer peripheral end portion of the protective oxide film. Moisture that has entered the semiconductor device progresses in the polyimide protective film and stays in the crack of the silicon nitride film, so that this portion becomes a starting point of a leak path to the polyimide protective film. In this case, since the polyimide protective film is in contact with the semiconductor substrate on a high voltage side which is an outer peripheral side relative to the termination region, there is a problem that the polyimide protective film undergoes dielectric breakdown when a rated voltage exceeding a test application condition is applied in an insulation inspection after completion of the test.

### SUMMARY

An object of the present disclosure is to provide a technique capable of improving reliability of a semiconductor device by preventing an outer peripheral end of an organic protective film from becoming a starting point of a leak path due to retained moisture.

A semiconductor device according to the present disclosure includes a semiconductor substrate, an electrode, a withstand voltage holding structure, an insulating protective film, a waterproof film, and an organic protective film. In the semiconductor substrate, a cell portion through which a main current flows and a termination portion surrounding an outer peripheral side of the cell portion are defined. The electrode is provided on an upper surface of the cell portion of the semiconductor substrate. The withstand voltage holding structure is provided in the termination portion of the semiconductor substrate and holds a withstand voltage. The insulating protective film covers an upper surface of the withstand voltage holding structure. The waterproof film covers at least the insulating protective film. The organic protective film covers a part of the waterproof film. An outer peripheral end portion of the electrode sits on an inner peripheral end portion of the insulating protective film. An inner peripheral end portion of the organic protective film sits on the outer peripheral end portion of the electrode. An outer peripheral end of the organic protective film is located on an inner peripheral side relative to an outer peripheral end of the insulating protective film.

Since the outer peripheral end of the organic protective film is separated from the semiconductor substrate, it is possible to prevent the outer peripheral end of the organic protective film from becoming a starting point of a leak path due to retained moisture. As a result, occurrence of dielectric breakdown of the organic protective film is suppressed, so that the reliability of the semiconductor device can be improved.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view of a semiconductor module according to a preferred embodiment;

FIG. 2 is a cross-sectional view of a main part of a semiconductor device according to the preferred embodiment;

FIG. 3 is a cross-sectional view of a main part of a semiconductor device according to a related art;

FIG. 4 is a cross-sectional view illustrating a state before a reliability test of the semiconductor device according to the related art;

FIG. 5 is a cross-sectional view illustrating a state during the reliability test of the semiconductor device according to the related art; and

FIG. 6 is a cross-sectional view illustrating a state during a property inspection after the reliability test of the semiconductor device according to the related art.

### DESCRIPTION OF THE PREFERRED EMBODIMENTS

### Preferred Embodiment

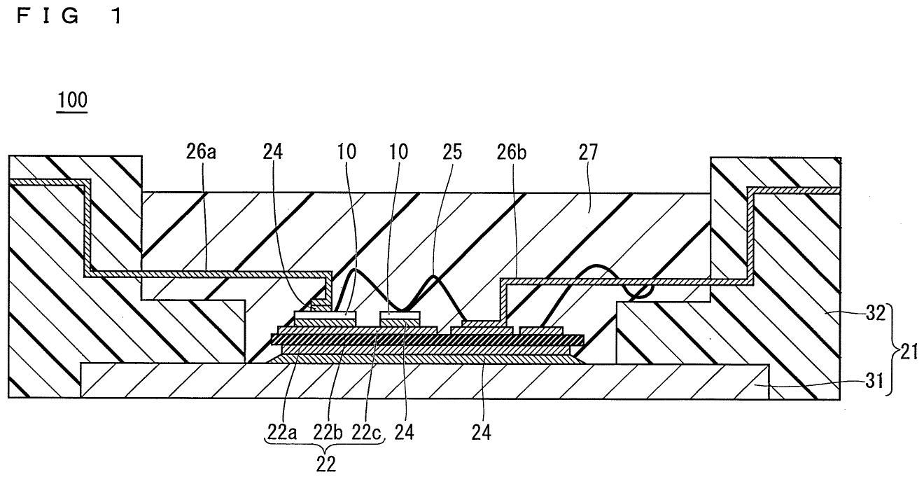

Hereinafter, a preferred embodiment will be described with reference to the drawings. FIG. 1 is a cross-sectional view of a semiconductor module 100 according to a preferred embodiment.

As illustrated in FIG. 1, the semiconductor module 100 includes a container 21, an insulating substrate 22, two semiconductor devices 10, a wire 25, external electrodes 26a and 26b, and a sealing material 27.

The container 21 includes a metal base plate 31 and a case 32. The case 32 has a rectangular frame shape in top view, and is attached to a peripheral edge portion of the metal base plate 31. The peripheral edge portion of the metal base plate 31 is attached to a lower end portion of an inner peripheral portion of the case 32.

The insulating substrate 22 includes an insulating layer 22b, a metal pattern 22a provided on a lower surface of the insulating layer 22b, and a circuit pattern 22c provided on an upper surface of the insulating layer 22b, and is joined onto the metal base plate 31 in the container 21 with a joining material 24.

The semiconductor devices 10 are mounted on the insulating substrate 22 with the joining material 24 interposed therebetween. The joining material 24 is a sinter joining material containing silver or copper. Although two semiconductor devices 10 are illustrated in FIG. 1, the number of semiconductor devices 10 may be one or may be two or more. Moreover, the number of external electrodes 26a and 26b is not limited to 2.

One end portion of the external electrode 26a is attached to the case 32, and the other end of the external electrode 26a is joined to one semiconductor device 10 with the joining material 24 interposed therebetween. One end portion of the external electrode 26b is attached to the case 32, and the other end of the external electrode 26b is joined to the circuit pattern 22c of the insulating substrate 22 with a joining material (not illustrated) interposed therebetween. The joining material for joining the external electrode 26b and the circuit pattern 22c is also a sinter joining material containing silver or copper.

The wire 25 connects the external electrode 26b and the circuit pattern 22c of the insulating substrate 22, and connects the semiconductor devices 10 to each other. Furthermore, the wire 25 connects the other semiconductor device 10 and the external electrode 26b.

The sealing material 27 fills the case 32 of the container 21 to seal the insulating substrate 22 and the semiconductor devices 10. That is, the sealing material 27 covers the semiconductor devices 10. The sealing material 27 is a curable gel.

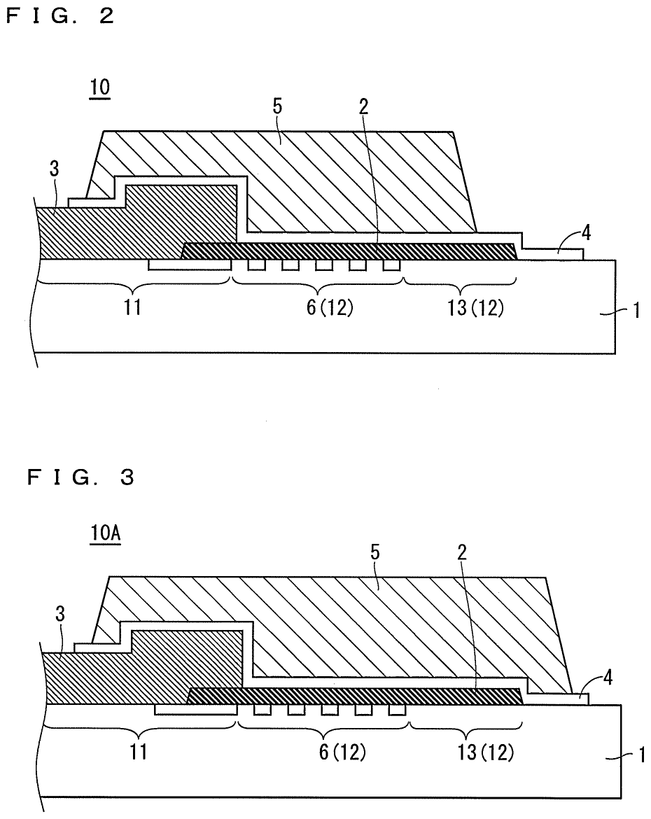

Next, the semiconductor device 10 will be described. FIG. 2 is a cross-sectional view of a main part of the semiconductor device 10 according to the preferred embodiment.

As illustrated in FIG. 2, the semiconductor device 10 includes a semiconductor substrate 1, an electrode 3, a withstand voltage holding structure 6, an insulating protective film 2, a waterproof film 4, and an organic protective film 5.

The semiconductor substrate 1 is mainly made of silicon carbide. That is, the semiconductor device 10 is a compound semiconductor device, more specifically, a silicon carbide semiconductor device. In the semiconductor substrate 1, a cell portion 11 and a termination portion 12 are defined. The cell portion 11 is an active region through which a current flows. The cell portion 11 is provided with a cell (not illustrated) for energization. The cell is formed, for example, by implanting freely-selected impurities into the semiconductor substrate 1 and diffusing the impurities, and a semiconductor element such as a metal oxide semiconductor field effect transistor (MOSFET) or a junction barrier Schottky (JBS) diode is formed in the cell, for example.

The electrode 3 covering the cell portion 11 is provided on an upper surface of the cell portion 11. For example, an aluminum electrode or the like is provided with a barrier metal interposed therebetween. As a main material of the electrode 3, metal such as copper can be used instead of aluminum.

The termination portion 12 is provided adjacent to an outer peripheral side of the cell portion 11 so as to surround the outer peripheral side of the cell portion 11. In the termination portion 12, the withstand voltage holding structure 6 that holds a withstand voltage and an excess region 13 are provided. The withstand voltage holding structure 6 is located on an inner peripheral side in the termination portion 12. The withstand voltage holding structure 6 is formed by, for example, implanting and diffusing freely-selected impurities into the semiconductor substrate 1, and is, for example, a guard ring structure. The guard ring structure includes a plurality of annular impurity layers and is formed in the flat semiconductor substrate 1. The excess region 13 is provided adjacent to an outer peripheral side of the withstand voltage holding structure 6 so as to cover the outer peripheral side of the withstand voltage holding structure 6.

The withstand voltage holding structure 6 and the excess region 13 in the termination portion 12 are provided in an upper portion of the semiconductor substrate 1. The insulating protective film 2 is provided on upper surfaces of the withstand voltage holding structure 6 and the excess region 13 so as to cover the upper surfaces of the withstand voltage holding structure 6 and the excess region 13. The insulating protective film 2 is, for example, an insulating film made of silicon dioxide, and exhibits high insulation by being provided on the upper surface of the flat semiconductor substrate 1. The insulating protective film 2 has a thickness of about 1 μm or more, and has a function of insulating the termination portion 12 from the outside.

As compared with a silicon semiconductor device having a semiconductor substrate mainly made of silicon, the semiconductor device 10, which is a silicon carbide semiconductor device, can achieve a reduction of the withstand voltage holding structure 6 and thereby achieve a reduction in cost, and the withstand voltage holding structure 6 can be more effectively reduced by covering the withstand voltage holding structure 6 with the insulating protective film 2. In order to avoid breakage of the insulating protective film 2 and impairing of the insulating properties, it is desirable that the insulating protective film 2 be provided so as not to reach an outer peripheral end of the semiconductor substrate 1 which is susceptible to chipping. In a portion where the insulating protective film 2 is in contact with the cell portion 11, the electrode 3 desirably sits on the insulating protective film 2. The waterproof film 4 is further provided on the insulating protective film 2.

The waterproof film 4 is formed of, for example, a film made of silicon nitride. The waterproof film 4 desirably extends to a position on the outer peripheral side relative to the insulating protective film 2 and not reaching a dicing region located at the outer peripheral end of the semiconductor substrate 1 so as to cover an outer peripheral end portion of the electrode 3 located close to the termination portion 12 and the insulating protective film 2.

Since the waterproof film 4 sits on only a step generated by the insulating protective film 2, the waterproof film 4 can be formed uniformly and can exhibit high waterproofness. The waterproof film 4 has a film density higher than that of the insulating protective film 2, and prevents moisture that has entered the semiconductor device 10 from spreading below the waterproof film 4. Although a film made of silicon oxide may transmit moisture, which leads to corrosion of the termination portion 12 such as the withstand voltage holding structure 6, a film made of silicon nitride can suitably prevent moisture from entering. In order to protect the waterproof film 4, the organic protective film 5 covering a part of the waterproof film 4 is provided on the waterproof film 4.

The organic protective film 5 is, for example, a protective film made of polyimide. An inner peripheral end portion of the organic protective film 5 sits on an outer peripheral end portion of the electrode 3 with the waterproof film 4 interposed therebetween. An outer peripheral end of the organic protective film 5 is located on the inner peripheral side relative to the outer peripheral end of the insulating protective film 2. The inner peripheral end portion of the organic protective film 5 covers the outer peripheral end portion of the electrode 3 in order to prevent a foreign substance from coming into contact with the electrode 3 and deteriorating insulation.

In the semiconductor device 10, which is a silicon carbide semiconductor device, a width of the termination portion 12 is shorter than that of a silicon semiconductor device, and creeping discharge easily occurs when shipping inspection or the like is performed in a state where the semiconductor device is exposed. Therefore, the outer peripheral portion of the electrode 3 may be covered with the organic protective film 5 to gain a creeping distance. The creeping discharge occurs, for example, between a low-voltage side where the electrode 3 is exposed and a high-voltage side where the semiconductor substrate 1 is exposed, and a creeping distance required varies depending on conditions of the shipping inspection or the like of the semiconductor device 10. Therefore, a length by which the outer peripheral portion of the electrode 3 is covered is also set freely.

However, when the organic protective film 5 is subjected to a durability test in which a voltage is continuously applied under a humidity environment, moisture may progress in the organic protective film 5 to generate a leak path. Therefore, it is desirable that the organic protective film 5 avoid contact with a portion where the semiconductor substrate 1 is exposed on the outer peripheral side of the semiconductor device 10.

As described above, the inner peripheral end portion of the organic protective film 5 sits on the electrode 3 and is in contact with the electrode 3 with the waterproof film 4 interposed therebetween. Although the waterproof film 4 also has an insulating property, it is difficult to avoid occurrence of a crack due to a step or the like located at a portion that sits on the electrode 3. At a corner portion of the electrode 3, a portion where the organic protective film 5 and the electrode 3 are electrically in contact with each other may occur. For example, stress is likely to concentrate at an upper corner portion of the electrode 3, and at a lower corner portion of the electrode 3, it is hard to uniformly form the waterproof film 4 due to a problem of coverage in deposition of the waterproof film 4 at a boundary of the insulating protective film 2.

When external force is applied during handling of the semiconductor device 10 or in a mounting process or the like, particularly the waterproof film 4, which is a thin film on the electrode 3, may develop a minute crack, and it is difficult to maintain insulation.

Since there is a portion where the organic protective film 5 is electrically in contact with the electrode 3 in the inner peripheral end portion of the organic protective film 5 as described above, in a case where the organic protective film 5 is in contact with a portion where the semiconductor substrate 1 is exposed on the outer peripheral side of the semiconductor device 10, the insulation of the organic protective film 5 may be deteriorated due to a leak path generated by moisture in the organic protective film 5. As a result, there is a possibility that dielectric breakdown of the organic protective film 5 occurs during application of a high voltage after humidity withstand voltage test.

Here, the contact encompasses a state in which the organic protective film 5 and the semiconductor substrate 1 are in electrical contact with each other with a gap interposed therebetween that is generated by a minute crack or coverage at a place where the waterproof film 4 sits on a step of the insulating protective film 2 or the like.

Therefore, by avoiding contact between the organic protective film 5 and the semiconductor substrate 1 on the high-voltage side, it is possible to prevent the organic protective film 5 from becoming a starting point of a leak path. In order to avoid contact between the organic protective film 5 and the semiconductor substrate 1 on the high-voltage side, the outer peripheral end of the organic protective film 5 is desirably located on the inner peripheral side relative to the outer peripheral side of the insulating protective film 2.

Furthermore, on the high-voltage side, which is the outer peripheral side relative to the termination portion 12, a portion of the insulating protective film 2 that is covered with the organic protective film 5 desirably avoids sitting on a groove, a step, or the like. Note that the groove or the step is one generated by patterning or the like, and in particular, it is desirable to avoid a groove or a step having a height difference larger than a thickness of the insulating protective film 2.

Although the cell portion 11 on the inner peripheral side relative to the termination portion 12 may have a step around a gate structure or the like, the step poses no problem since a voltage during application of a withstand voltage is not applied to this portion. Since the organic protective film 5 is provided for the purpose of protecting the withstand voltage holding structure 6 from an external factor, it is desirable that the organic protective film 5 extends to the outer peripheral side relative to the withstand voltage holding structure 6.

Furthermore, since the waterproof film 4 is provided for the purpose of preventing moisture from entering the withstand voltage holding structure 6, it is desirable that the waterproof film 4 extends to the outer peripheral side relative to the withstand voltage holding structure 6. In addition, the waterproof film 4 needs to prevent moisture from entering below the insulating protective film 2 at the outer peripheral end of the organic protective film 5 in order to prevent the outer peripheral end of the organic protective film 5 from becoming a starting point of a leak path. Therefore, it is desirable that the waterproof film 4 extends to the outer peripheral side relative to the organic protective film 5. Moreover, it is desirable that the waterproof film 4 extends to the outer peripheral side relative to the insulating protective film 2. The outer peripheral end of the insulating protective film 2 has a step, and the waterproof film 4 may develop a crack at the step. However, since the outer peripheral end of the organic protective film 5 is separated from the semiconductor substrate 1, it is possible to prevent the outer peripheral end of the organic protective film 5 from becoming a starting point of a leak path due to retained moisture.

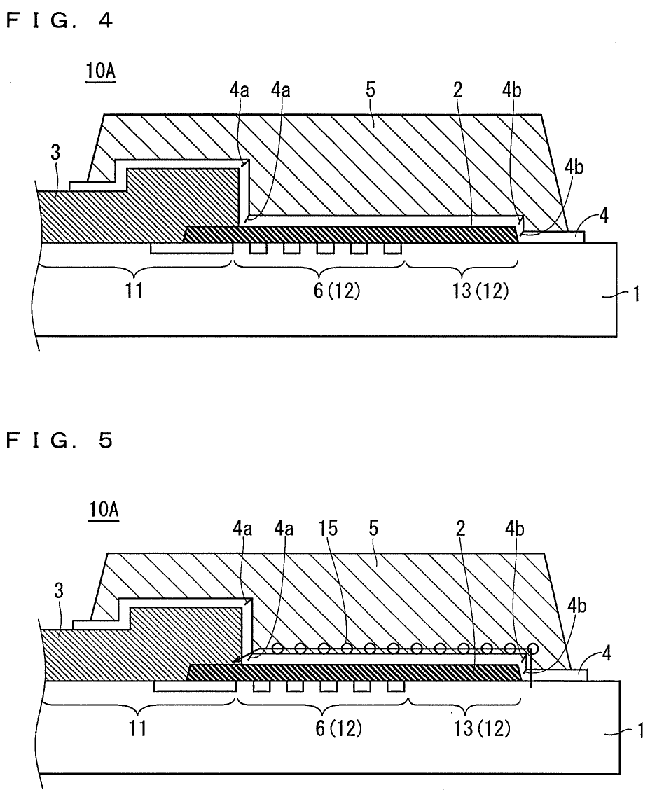

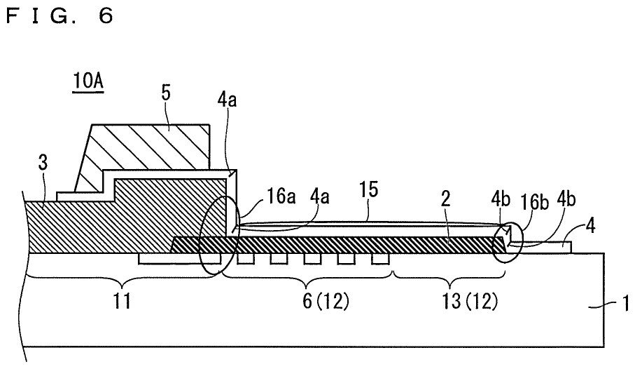

Next, implementation of a reliability test and a characteristic inspection on the semiconductor module 100 on which the semiconductor device 10 is mounted will be described in comparison with a case where a semiconductor device 10A according to a related art is mounted. FIG. 3 is a cross-sectional view of a main part of the semiconductor device 10A according to the related art. FIG. 4 is a cross-sectional view illustrating a state before a reliability test of the semiconductor device 10A according to the related art. FIG. 5 is a cross-sectional view illustrating a state during the reliability test of the semiconductor device 10A according to the related art. FIG. 6 is a cross-sectional view illustrating a state during a characteristic inspection after the reliability test of the semiconductor device 10A according to the related art.

After an electrical characteristic inspection is performed on the semiconductor device 10, the semiconductor device 10 is mounted on the semiconductor module 100, as illustrated in FIG. 1. The semiconductor device 10 and the circuit pattern 22c, and the semiconductor device 10 and the external electrode 26a are connected by solder joining using a solder material or by sinter joining using a sinter joining material containing silver or copper. As in the present exemplary embodiment, the semiconductor device 10 is a silicon carbide semiconductor device, and when the semiconductor module 100 is used at a high temperature, the joining material 24 is desirably one having high heat resistance, such as a sinter joining material.

When the semiconductor device 10 is joined by sinter joining, pressure is applied. If a foreign substance is caught between the semiconductor device 10 and the external electrode 26a when pressure is applied during sinter joining between the semiconductor device 10 and the external electrode 26a, the electrode 3 of the semiconductor device 10 is short-circuited and thereby yield of the semiconductor module 100 decreases. However, since the outer peripheral portion of the electrode 3 is covered with the organic protective film 5, occurrence of defective products can be reduced.

After connection between the semiconductor device 10 and the circuit pattern 22c, wire bonding, and connection between the external electrodes 26a and 26b are performed, the sealing material 27 is introduced. The sealing material 27 is, for example, a curable gel. By using the curable gel, insulation can be easily secured even in a case where the semiconductor device 10 is relatively large, so that both manufacturability and reliability of the semiconductor device 10 can be achieved. However, since the gel easily permits entry of moisture, moisture resistance needs to be improved especially in the outer peripheral portion of the semiconductor device 10.

Here, the semiconductor device 10A according to the related art will be described. As illustrated in FIG. 2, in the semiconductor device 10, the outer peripheral end of the organic protective film 5 is located on the inner peripheral side relative to the outer peripheral end of the insulating protective film 2, whereas, as illustrated in FIG. 3, in the semiconductor device 10A, the outer peripheral end of the organic protective film 5 is located on the outer peripheral side relative to the outer peripheral end of the insulating protective film 2. More specifically, the inner peripheral end of the organic protective film 5 is in contact with the electrode 3 with the waterproof film 4 interposed therebetween, and the outer peripheral end of the organic protective film 5 is in contact with the semiconductor substrate 1 with the waterproof film 4 interposed therebetween. The semiconductor device 10 and the semiconductor device 10A have the same structure except for this.

Various reliability tests are performed on the semiconductor module 100 to evaluate a failure risk in the market. A typical test for evaluating moisture resistance is the High Voltage High Humidity High Temperature Reverse Bias (H3TRB) test. The H3TRB test is, for example, a test in which a test of applying a voltage of 80% of withstand voltage rating under a 85% RH humidity environment is performed for 1000 hours, and after the test, a voltage of 100% of the withstand voltage rating is applied to perform an inspection for checking characteristic fluctuation or the presence or absence of breakdown and deterioration.

In the semiconductor module on which the semiconductor device 10A is mounted, cracks 4a and 4b were generated in a portion of the waterproof film 4 that sits on the electrode 3 and a portion of the waterproof film 4 that sits on the insulating protective film 2 before the reliability test, as illustrated in FIG. 4. Note that FIGS. 4 to 6 illustrate only the semiconductor device 10A of the semiconductor module.

Next, as illustrated in FIG. 5, after the reliability test, a leak path 15 formed by moisture was generated through the cracks 4a and 4b by application of a voltage of 85% of the rated withstand voltage. Next, as illustrated in FIG. 6, dielectric breakdowns 16a and 16b occur due to the leak path 15 in some test samples during the characteristic inspection after the reliability test, that is, at a time of application of the voltage of 100% of the rated withstand voltage after the reliability test. That is, a dielectric breakdown failure of the organic protective film 5 occurred.

In particular, since the waterproof film 4 is provided on the insulating protective film 2, the dielectric breakdown mode of the organic protective film 5 becomes apparent. This result suggests that the waterproof film 4 failed to insulate the organic protective film 5 and the semiconductor substrate 1 from each other and insulate the organic protective film 5 and the electrode 3 from each other, and it is presumed that since the waterproof film 4 was provided, moisture that entered from the sealing material 27 remained on the waterproof film 4 without moving to a lower side of the insulating protective film 2, so that a state in which the leak path 15 is likely to occur in the organic protective film 5 was created.

On the other hand, in the semiconductor module 100 on which the semiconductor device 10 according to the preferred embodiment is mounted, it has been confirmed that dielectric breakdown of the organic protective film 5 starting from a leak path does not occur after the reliability test by adopting the structure in which the outer peripheral end of the organic protective film 5 is kept located on the insulating protective film 2.

As described above, the semiconductor device 10 according to the preferred embodiment includes the semiconductor substrate 1 in which the cell portion 11 through which a main current flows and the termination portion 12 surrounding the outer peripheral side of the cell portion 11 are defined, the electrode 3 provided on the upper surface of the cell portion 11 of the semiconductor substrate 1, the withstand voltage holding structure 6 provided in the termination portion 12 of the semiconductor substrate 1 and holding a withstand voltage, the insulating protective film 2 covering the upper surface of the withstand voltage holding structure 6, the waterproof film 4 covering at least the insulating protective film 2, and the organic protective film 5 covering a part of the waterproof film 4. The outer peripheral end portion of the electrode 3 sits on the inner peripheral end portion of the insulating protective film 2. The inner peripheral end portion of the organic protective film 5 sits on the outer peripheral end portion of the electrode 3. An outer peripheral end of the organic protective film 5 is located on the inner peripheral side relative to the outer peripheral end of the insulating protective film 2.

Therefore, the outer peripheral end of the organic protective film 5 is separated from the semiconductor substrate 1, and it is therefore possible to prevent the outer peripheral end of the organic protective film 5 from becoming a starting point of the leak path 15 due to retained moisture. As a result, occurrence of dielectric breakdown of the organic protective film 5 is suppressed, so that the reliability of the semiconductor device 10 can be improved.

Furthermore, since the waterproof film 4 covers the outer peripheral end portion of the electrode 3 located close to the termination portion, and the inner peripheral end portion of the organic protective film 5 sits on the outer peripheral end portion of the electrode 3 with the waterproof film 4 interposed therebetween, the organic protective film 5 protects the outer peripheral end portion of the electrode 3, so that it is possible to prevent a foreign substance from coming into contact with the electrode 3 and causing short-circuit of the electrode 3.

Furthermore, since the outer peripheral end of the organic protective film 5 is located on the outer peripheral side relative to the outer peripheral end of the withstand voltage holding structure 6, and the outer peripheral end of the waterproof film 4 is located on the outer peripheral side relative to the outer peripheral end of the organic protective film 5, it is possible to prevent moisture from entering the lower side of the insulating protective film 2.

Furthermore, since the outer peripheral end of the waterproof film 4 is located on the outer peripheral side relative to the outer peripheral end of the insulating protective film 2, it is possible to prevent moisture from entering the lower side of the insulating protective film 2.

The semiconductor module 100 includes the semiconductor device 10 and the sealing material 27 covering the semiconductor device 10, and the sealing material 27 is a curable gel. Therefore, insulation can be easily secured even in a case where the semiconductor device 10 is relatively large, so that both manufacturability and reliability of the semiconductor device 10 can be achieved.

The semiconductor module 100 further includes the external electrode 26a connected to the semiconductor device 10 with the joining material 24 interposed therebetween, and the joining material 24 is a sinter joining material. When the semiconductor device 10 is joined by sinter joining, pressure is applied. If a foreign substance is caught between the semiconductor device 10 and the external electrode 26a when pressure is applied during sinter joining between the semiconductor device 10 and the external electrode 26a, the electrode 3 of the semiconductor device 10 is short-circuited and thereby yield of the semiconductor module 100 decreases. However, since the outer peripheral portion of the electrode 3 is covered with the organic protective film 5, occurrence of defective products can be reduced.

The semiconductor device 10 is a compound semiconductor device. More specifically, the semiconductor device 10 is a silicon carbide semiconductor device. In the compound semiconductor device, the width of the termination portion 12 can be shortened, but shortening the width of the termination portion 12 increases an electric field applied to the organic protective film 5, generates the leak path 15 in the organic protective film 5, and increases a possibility that the organic protective film 5 is broken in a subsequent rated withstand voltage test. As described above, in the preferred embodiment, occurrence of dielectric breakdown of the organic protective film 5 is suppressed, and therefore a reduction in cost of the semiconductor device 10 can be achieved by shortening the width of the termination portion 12, and the reliability of the semiconductor device 10 can be enhanced.

Note that the preferred embodiment can be appropriately modified or omitted.

Various aspects of the present disclosure will be collectively described below as an appendix.

### (Appendix 1)

A semiconductor device comprising:
a semiconductor substrate in which a cell portion through which a main current flows and a termination portion surrounding an outer peripheral side of the cell portion are defined;
an electrode provided on an upper surface of the cell portion of the semiconductor substrate;
a withstand voltage holding structure that is provided in the termination portion of the semiconductor substrate and holds a withstand voltage;
an insulating protective film covering an upper surface of the withstand voltage holding structure;
a waterproof film covering at least the insulating protective film; and
an organic protective film covering a part of the waterproof film, wherein
an outer peripheral end portion of the electrode sits on an inner peripheral end portion of the insulating protective film,
an inner peripheral end portion of the organic protective film sits on the outer peripheral end portion of the electrode, and
an outer peripheral end of the organic protective film is located on an inner peripheral side relative to an outer peripheral end of the insulating protective film.

### (Appendix 2)

The semiconductor device according to Appendix 1, wherein
the waterproof film covers the outer peripheral end portion of the electrode located close to the termination portion, and
the inner peripheral end portion of the organic protective film sits on the outer peripheral end portion of the electrode with the waterproof film interposed therebetween.

### (Appendix 3)

The semiconductor device according to Appendix 1 or 2, wherein
the outer peripheral end of the organic protective film is located on an outer peripheral side relative to an outer peripheral end of the withstand voltage holding structure, and
an outer peripheral end of the waterproof film is located on an outer peripheral side relative to the outer peripheral end of the organic protective film.

### (Appendix 4)

The semiconductor device according to any one of Appendixes 1 to 3, wherein the outer peripheral end of the waterproof film is located on an outer peripheral side relative to the outer peripheral end of the insulating protective film.

### (Appendix 5)

A semiconductor module comprising:
the semiconductor device according to any one of Appendixes 1 to 4; and
a sealing material that covers the semiconductor device, wherein
the sealing material is a curable gel.

### (Appendix 6)

The semiconductor module according to Appendix 5, further comprising an external electrode connected to the semiconductor device with a joining material interposed therebetween, wherein
the joining material is a sinter joining material.

### (Appendix 7)

The semiconductor module according to Appendix 5 or 6, wherein the semiconductor device is a compound semiconductor device.

### (Appendix 8)

The semiconductor module according to Appendix 7, wherein the semiconductor device is a silicon carbide semiconductor device.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate in which a cell portion through which a main current flows and a termination portion surrounding an outer peripheral side of the cell portion are defined;
an electrode provided on an upper surface of the cell portion of the semiconductor substrate;
a withstand voltage holding structure that is provided in the termination portion of the semiconductor substrate and holds a withstand voltage;
an insulating protective film covering an upper surface of the withstand voltage holding structure;
a waterproof film covering at least the insulating protective film; and
an organic protective film covering a part of the waterproof film, wherein
an outer peripheral end portion of the electrode sits on an inner peripheral end portion of the insulating protective film,
an inner peripheral end portion of the organic protective film sits on the outer peripheral end portion of the electrode, and
an outer peripheral end of the organic protective film is located on an inner peripheral side relative to an outer peripheral end of the insulating protective film.

2. The semiconductor device according to claim 1, wherein
the waterproof film covers the outer peripheral end portion of the electrode located close to the termination portion, and
the inner peripheral end portion of the organic protective film sits on the outer peripheral end portion of the electrode with the waterproof film interposed therebetween.

3. The semiconductor device according to claim 1, wherein
the outer peripheral end of the organic protective film is located on an outer peripheral side relative to an outer peripheral end of the withstand voltage holding structure, and
an outer peripheral end of the waterproof film is located on an outer peripheral side relative to the outer peripheral end of the organic protective film.

4. The semiconductor device according to claim 3, wherein the outer peripheral end of the waterproof film is located on an outer peripheral side relative to the outer peripheral end of the insulating protective film.

5. A semiconductor module comprising:
the semiconductor device according to claim 1; and
a sealing material that covers the semiconductor device, wherein
the sealing material is a curable gel.

6. The semiconductor module according to claim 5, further comprising an external electrode connected to the semiconductor device with a joining material interposed therebetween, wherein
the joining material is a sinter joining material.

7. The semiconductor module according to claim 5, wherein the semiconductor device is a compound semiconductor device.

8. The semiconductor module according to claim 7, wherein the semiconductor device is a silicon carbide semiconductor device.
